(19) United States
(12) Patent Application Publication
(10) Pub. No.: US 2008/0213702 A1
(43) Pub. Date: Sep. 4, 2008

(54) METHOD FOR PATTERNING CONDUCTIVE POLYMER

(76) Inventors: Yang-Ho BAE, Seoul (KR); Chang-Oh JEONG, Suwon-si (KR); Byeong-Beom KIM, Suwon-si (KR); Jae-Gab LEE, Seoul (KR); Tae-Wook KWON, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/932,496

(22) Filed: Oct. 31, 2007

(30) Foreign Application Priority Data
Nov. 28, 2006 (KR) 10-2006-0118233

(51) Int. Cl. G03F 7/00

(52) U.S. Cl. 430/315

(57) ABSTRACT

A method for patterning a conductive polymer that adheres well to an oxide layer is presented. The method includes forming a self-assembled monolayer on a substrate, patterning the self-assembled monolayer, forming a catalyst layer on the self-assembled monolayer, and forming a conductive polymer layer on the self-assembled monolayer.

### CROSS-REFERENCE TO RELATED APPLICATION

The present application claims priority to Korean Patent Application No. 2006-118233 filed on Nov. 28, 2006, the disclosure of which is incorporated herein by reference in its entirety.

### BACKGROUND OF THE INVENTION

1. Field of the Invention

The present disclosure relates to a method for patterning a conductive polymer capable of adhering to an oxide layer.

2. Description of the Related Art

Much research on a variety of conductive polymers and substrates is conducted to improve organic thin film transistors that have gained popularity as a next generation display device. Of the different types of organic thin film transistors, poly 3,4-ethylenedioxythiophene (PEDOT), one of the conductive polymers, has especially attracted much attention due to its advantages in that it is transparent in the visible range, is electrochemically stable, and can provide conductor characteristics as well as semiconductor characteristics depending on the dopant concentration.

Moreover, PEDOT provides the advantage of allowing the thickness of a high purity conductive polymer to be adjusted to a nano-scale level by a vapor deposition process using an oxidizing agent.

However, the vapor-deposited PEDOT has some problems. First, it does not adhere securely enough to an oxide layer such as TiO₂, ZrO₂, HfO₂, etc. that have been studied as useful materials for an insulating layer that can improve the organic thin film transistor characteristics. Furthermore, it is difficult to form a pattern with the vapor-deposited PEDOT due to the absence of selectivity between the conductive polymer and a photoresist.

### SUMMARY OF THE INVENTION

The present invention provides a method for patterning a conductive polymer that is adhesive to an oxide layer.

In one aspect, the present invention provides a method for patterning a conductive polymer. The method comprises forming a self-assembled monolayer on a substrate, patterning the self-assembled monolayer, forming a catalyst layer on the self-assembled monolayer, and forming a conductive polymer layer on the self-assembled monolayer.

The method for patterning a conductive polymer may include forming an insulating layer between the substrate and the self-assembled monolayer.

The conductive polymer layer may include a polythiophene based material or a polyaniline based material.

The conductive polymer layer may include a poly 3,4-ethylenedioxythiophene (PEDOT).

Forming the self-assembled monolayer may entail preparing a self-assembled monolayer solution by dissolving the self-assembled monolayer in a solvent, and dipping the substrate on which an oxide layer is formed in the self-assembled monolayer solution.

The solvent may be hexane.

Patterning the self-assembled monolayer may include forming a mask defining an exposure area and a non-exposure area in the self-assembled monolayer; aligning the mask on the substrate; and irradiating the mask with ultraviolet light.

The mask may have a blocking layer of a chromium material formed on a quartz substrate.

The mask may be irradiated for about 10 to 15 minutes.

The catalyst layer may be formed using a spin coating process.

The catalyst may be an oxidizing agent and the oxidizing agent such as FeCl₃.

The conductive polymer layer may be formed using a vapor deposition process.

Forming the conductive polymer layer may include heating 3,4-Ethylenedioxythiophene (EDOT) to be vaporized, and forming a PEDOT layer by depositing the vaporized EDOT on the substrate.

Patterning a conductive polymer may include removing organic materials on the substrate before forming the self-assembled monolayer.

Removing the organic materials may be done by dipping the substrate in a detergent solution and rinsing the substrate.

The detergent solution may be a solution of sulfuric acid (H₂SO₄) and hydrogen peroxide (H₂O₂) mixed in a volumetric ratio of 4:1.

The method for patterning a conductive polymer may also include removing the catalyst remaining on the substrate after forming the conductive polymer layer.

The substrate may be rinsed using a catalyst removing solvent.

The catalyst removing solvent may be methanol.

The insulating layer may be an oxide layer that includes at least one of SiO₂, TiO₂, ZrO₂ and HfO₂.

### BRIEF DESCRIPTION OF THE DRAWINGS

Exemplary embodiments of the present invention can be understood in more detail from the following descriptions taken in conjunction with the accompanying drawings, in which:

FIGS. 1 to 7 are cross-sectional views showing a method for patterning a conductive polymer in accordance with a preferred embodiment of the present invention;

FIG. 8 is a schematic diagram showing a structure of a self-assembled monolayer in accordance with a preferred embodiment of the present invention;

FIG. 9 is an optical microscopic photograph of a substrate formed in accordance with Comparative Example 1;

FIG. 10 is an optical microscopic photograph of a substrate formed in accordance with Comparative Example 2;

FIG. 11 is an optical microscopic photograph of a substrate formed in accordance with Example 1;

FIG. 12 is an optical microscopic photograph of a substrate formed in accordance with Example 2;

FIG. 13 is a graph showing contact angles measured by exposing a substrate, on which a self-assembled monolayer is formed, to ultraviolet rays by varying the exposure time; and

FIG. 14 is a graph showing results of X-ray analyses obtained by exposing a substrate, on which a self-assembled monolayer is formed, to ultraviolet rays by varying the exposure time.

### DESCRIPTION OF THE EMBODIMENTS

Detailed operations and exemplary embodiments of the invention are described more fully hereinafter with reference with the accompanying drawings.

The present invention may, however, be embodied in many different forms and should not be construed as limited to the exemplary embodiments set forth herein.

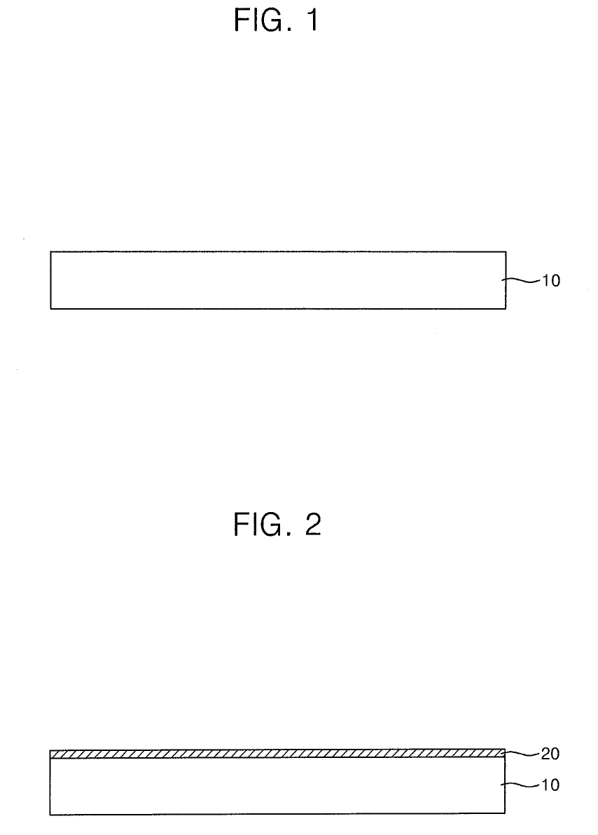

FIG. 1 to FIG. 7 are cross-sectional views showing a method for patterning a conductive polymer in accordance with the present invention.

A substrate 10 is prepared as shown in FIG. 1 and an oxide layer 20 is formed on the substrate 10 as shown in FIG. 2. The oxide layer 20 may be one of SiO₂, TiO₂, ZrO₂ and HfO₂. Although this is not a requirement of the invention, using SiO₂ as the oxide layer 20 may be preferable since it is possible to form the SiO₂ layer by heating a silicon wafer. That is, the oxide layer 20 is formed by heating the substrate 10, as shown FIG. 2. In the present invention, the SiO₂ layer is formed to have a thickness in a range from about 800 Å to about 1200 Å.

Subsequently, the substrate 10 having the oxide layer 20 is rinsed. The rinsing removes organic materials remaining on the substrate 10 and the oxide layer 20. If any organic material is present on the oxide layer 20, it is difficult to obtain a uniform self-assembled monolayer (SAM) later in the process.

In the present invention, the organic materials are removed by dipping the substrate having the oxide layer 20 in a detergent solution for a certain period of time. The detergent solution to be used is prepared by mixing sulfuric acid (H₂SO₄) and hydrogen peroxide (H₂O₂) in a volumetric ratio of 4:1. It is preferable that the substrate be dipped in the detergent solution for 8 to 12 minutes. If the time of dipping the substrate in the detergent solution is less than 8 minutes, the organic materials may not be removed. Whereas, if it exceeds 12 minutes, the oxide layer formed on the substrate may be affected.

Moreover, it is desirable that the surface of the substrate 10 be rinsed using deionized (DI) water in order to prevent contamination of the substrate 10.

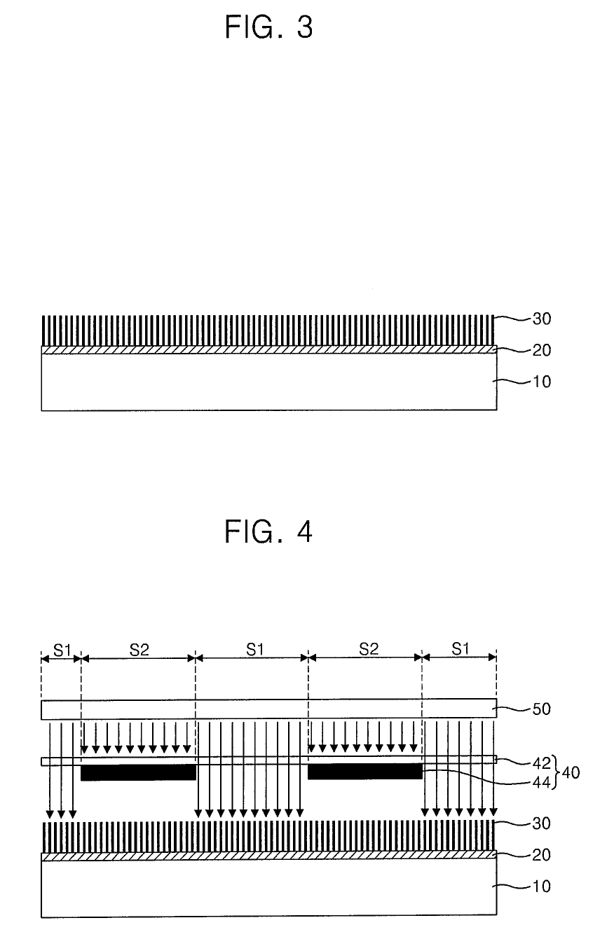

Next, a self-assembled monolayer 30 is formed on the oxide layer 20 as shown in FIG. 3. In the present invention, the self-assembled monolayer 30 is formed as an octadecyltrichlorosilane (OTS) based self-assembled monolayer. The OTS based self-assembled monolayer has an advantage in that it can easily form a monolayer on the oxide layer 20. In the present invention, the self-assembled monolayer 30 is formed in a dipping process.

The method for forming the self-assembled monolayer will be described in more detail as follows.

First, a self-assembled monolayer solution is prepared by dissolving the self-assembled monolayer in a solvent. In the present invention, hexane is used as the solvent. Then, the substrate having the oxide layer is dipped in the self-assembled monolayer solution. Like this, the self-assembled monolayer is formed on the oxide layer only by dipping the oxide layer in the self-assembled monolayer solution, which results from the characteristics of the self-assembled monolayer.

FIG. 8 is a schematic diagram of a structure of the OTS based self-assembled monolayer used in the present invention. As shown in the figure, a molecule of the self-assembled monolayer 30 comprises a hydrophobic surface 32, a chain portion 34 and a reaction portion 36. The hydrophobic surface 32 has a hydrophobicity due to the presence of a CH₃ group. The hydrophobic surface 32 is exposed to the surface during the formation of the self-assembled monolayer 30. The chain portion 34 is a portion connecting the hydrophobic surface 32 to the reactive portion 36 and comprising a CH₂ chain. The reactive portion 36 is a portion connected to the oxide layer 20 by reacting with the oxide layer 20.

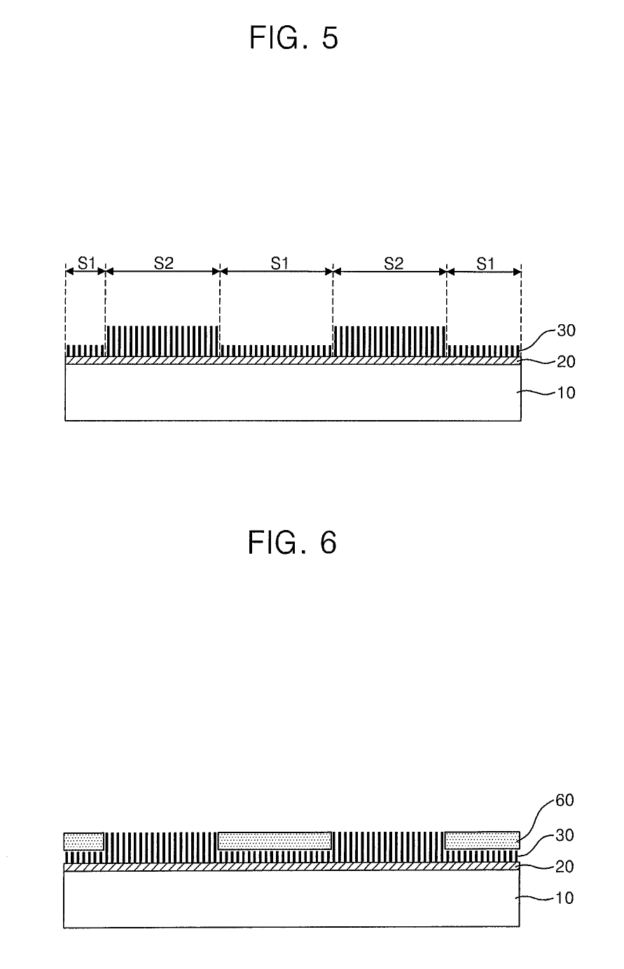

Referring to FIGS. 4 and 5, the self-assembled monolayer 30 formed on the oxide layer 20 is patterned. In the present invention, the self-assembled monolayer 30 is patterned using an ultraviolet light irradiation. The method for patterning the self-assembled monolayer will be described in more detail as follows.

First, a mask 40 defining an exposure area S1 and a non-exposure area S2 in the self-assembled monolayer is manufactured. The exposure area S1 is an area exposed to ultraviolet light to remove hydrophobic properties of the self-assembled monolayer 30 and to have hydrophilic properties. In this area where the hydrophobic properties are removed and the hydrophilic properties are given, a conductive polymer layer is formed in the following process. Accordingly, the area in which the conductive polymer layer will be formed should be defined as the exposure area S1. The non-exposure area S2 is an area to which the ultraviolet light is not irradiated and has the hydrophilic properties of the self-assembled monolayer. Accordingly, the non-exposure area S2 is an area in which the conductive polymer layer is not formed in the following process.

As shown in FIG. 4, the mask 40 is formed in a structure in which a chromium light-blocking layer 44 is formed on a quartz substrate 42. Accordingly, an area where the chromium light-blocking layer 44 is formed corresponds to the non-exposure area S2, and an area where the chromium light-blocking layer 44 is not formed corresponds to the exposure area S1.

Next, the mask 40 is aligned on the substrate 10. A mark (not shown) is formed on the substrate 10 for the purpose of an exact alignment of the mask 40 and an exact alignment operation is carried out using the mark. Then, as shown in FIG. 4, the ultraviolet light is irradiated onto the top of the mask 40 aligned on the substrate 10.

The ultraviolet light used in the present invention preferably has a wavelength of about 185 to about 254 nm and is applied for about 10 to about 15 minutes. If the ultraviolet light is applied less than 10 minutes, the hydrophobicity of the self-assembled monolayer is not converted to hydrophilicity sufficiently. On the other hand, if the ultraviolet light is applied for more than about 15 minutes, the self-assembled monolayer may be totally destroyed and nothing exists on the oxide layer.

Like this, if the ultraviolet light is applied for a certain time, the self-assembled monolayer exposed to the ultraviolet light is changed to have the hydrophilicity as shown in FIG. 5. In more detail, the CH₃ group of the hydrophobic surface 32 is destroyed by an oxygen radical generated by the ultraviolet light, and a hydrophilic group such as C—O or C═O is formed. As a result, the portion exposed to the ultraviolet light becomes hydrophilic.

As shown in FIG. 6, a catalyst layer 60 is formed on the patterned self-assembled monolayer 30. In the present invention, the catalyst layer 60 is formed using a spin coating process. The reason that the catalyst layer 60 can be formed using the spin coating process is that the catalyst has a hydrophilicity. Even if the catalyst having the hydrophilicity is coated on the whole surface of the substrate 10, the catalyst layer 60 is formed only on the portions transformed to have the hydrophilicity by the ultraviolet light in the self-assembled monolayer as shown in FIG. 6. That is, the catalyst layer 60 is selectively formed by the patterned self-assembled monolayer 30.

The catalyst used in the present invention is an oxidizing agent promoting the reaction for forming the conductive polymer layer on the self-assembled monolayer. The catalyst may be FeCl₃.

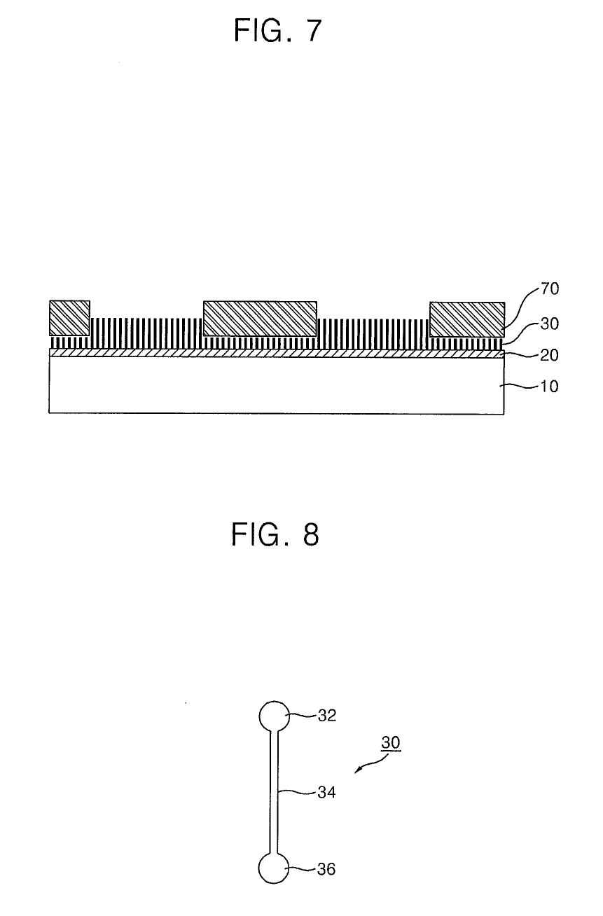

As shown in FIG. 7, a conductive polymer layer 70 is formed on the self-assembled monolayer 30. In the present invention, the conductive polymer layer 70 is formed using a vapor deposition process. In more detail, an appropriate amount of 3,4-ethylenedioxythiophene (EDOT) is filled in an evaporation vessel and then heated to vaporize the EDOT. Subsequently, the vaporized EDOT molecules are deposited on the substrate 10. Then, the EDOT molecules are combined with each other to form a PEDOT layer 70 on the substrate 10.

After the formation of the conductive polymer layer 70, the catalyst remaining on the substrate 10 is removed. During this process, the catalyst is removed by rinsing the substrate surface using a catalyst removal solution. If any catalyst remains on the substrate, characteristics may become deteriorated when the conductive polymer layer is used as an electrode of a transistor and the like. Accordingly, it is required to clean the catalyst neatly.

In the present invention, methanol may be used as the catalyst removal solution. That is, the substrate on which the conductive polymer deposition process is completed is rinsed neatly by dipping the same in the methanol solution.

Examples of the present invention will be described with Comparative Examples below.

### Comparative Example 1

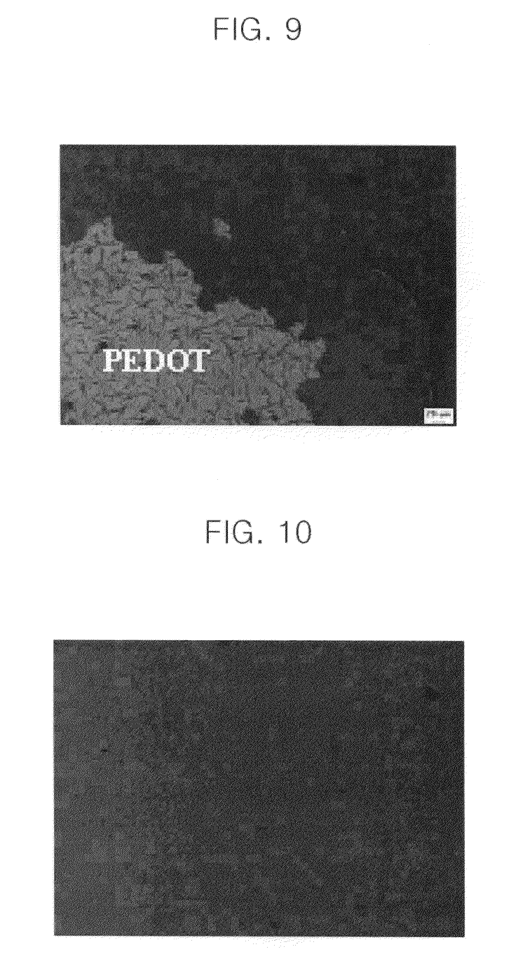

A silicon wafer formed by growing a thermal oxide layer of 1000 Å was used as a substrate. After dipping the wafer in a solution of H₂SO₄ and H₂O₂ mixed in a volumetric ratio of 4:1 for about 10 minutes, the wafer was rinsed with DI water to remove organic materials remaining on the substrate surface. Subsequently, FeCl₃ was uniformly coated on the substrate surface using a spin coater and PEDOT was deposited on the sample by vaporizing EDOT using an oven. The deposited PEDOT was washed using methanol. FIG. 9 is an optical microscopic photograph of the thus obtained substrate.

### Comparative Example 2

In Comparative Example 2, PEDOT was deposited in substantially the same manner as in Comparative Example 1, except that an octadecyltrichlorosilane (OTS) based self-assembled monolayer was formed on the whole surface of a silicon wafer on which an oxide layer was formed. FIG. 10 is an optical microscopic photograph of the thus obtained substrate.

### Example 1

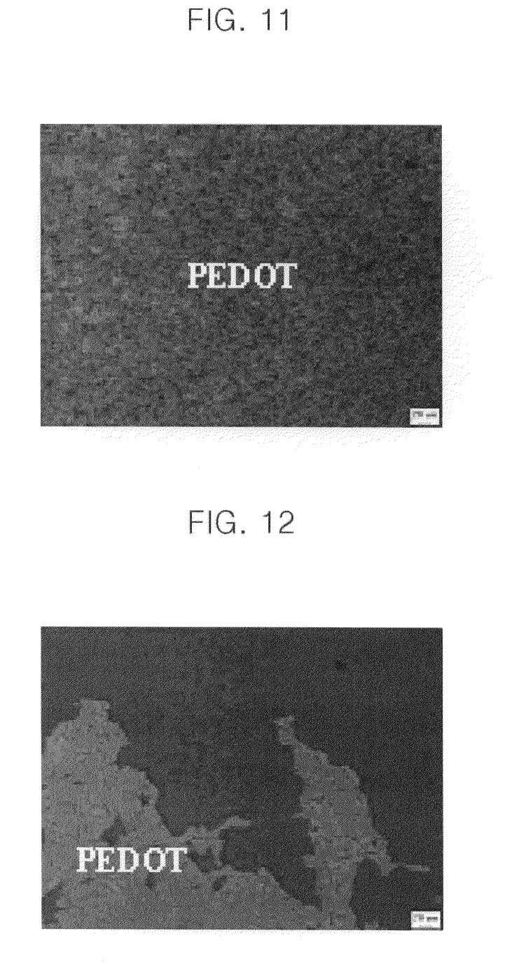

In Example 1, PEDOT was deposited in substantially the same manner as in Comparative Example 2 except that a self-assembled monolayer was formed on the whole surface of a silicon wafer, which was exposed to ultraviolet light for about 150 seconds. FIG. 11 is an optical microscopic photograph of the thus obtained substrate.

### Example 2

In Example 2, PEDOT was deposited in substantially the same process as in Example 1 except that the silicon wafer was exposed to the ultraviolet light for about 30 minutes. FIG. 12 is an optical microscopic photograph of the thus obtained substrate.

FIG. 9 to FIG. 12 are analyzed as follows:

First, referring to FIG. 9, in Comparative Example 1, PEDOT was deposited on the oxide layer without any special pretreatment. FIG. 9 shows that the coating of the oxidizing agent and the deposition of the PEDOT were well done. However, the PEDOT layer was separated from the substrate during the methanol washing process due to weak adhesive strength between the oxide layer and the PEDOT layer.

Referring to FIG. 10, in Comparative Example 2, the self-assembled monolayer was generally formed on the oxide layer and the PEDOT layer was deposited thereon. However, FIG. 10 shows that the oxidizing agent was not coated due to the CH₃ of the hydrophobic surface of the self-assembled monolayer.

Meanwhile, FIG. 11 shows that FeCl₃ as the oxidizing agent showed excellent applicability as the surface modification change of the self-assembled monolayer proceeded extensively. Thus, the deposition of the PEDOT layer was carried out stably. Moreover, since the adhesive property between the PEDOT layer and the oxide layer was excellent, the PEDOT layer was not separated from the substrate in the methanol washing process.

Moreover, referring to FIG. 12, in Example 2, the CH₂ chains of the OTS as the self-assembled monolayer were completely removed by exposing the self-assembled monolayer to the ultraviolet light for a long time, thus resulting in the same state in which the self-assembled monolayer did not exist. Accordingly, the PEDOT layer deposited in the manner described for FIG. 9 was separated again from the substrate in the methanol washing process due to the low adhesive strength between the PEDOT layer and the oxide layer.

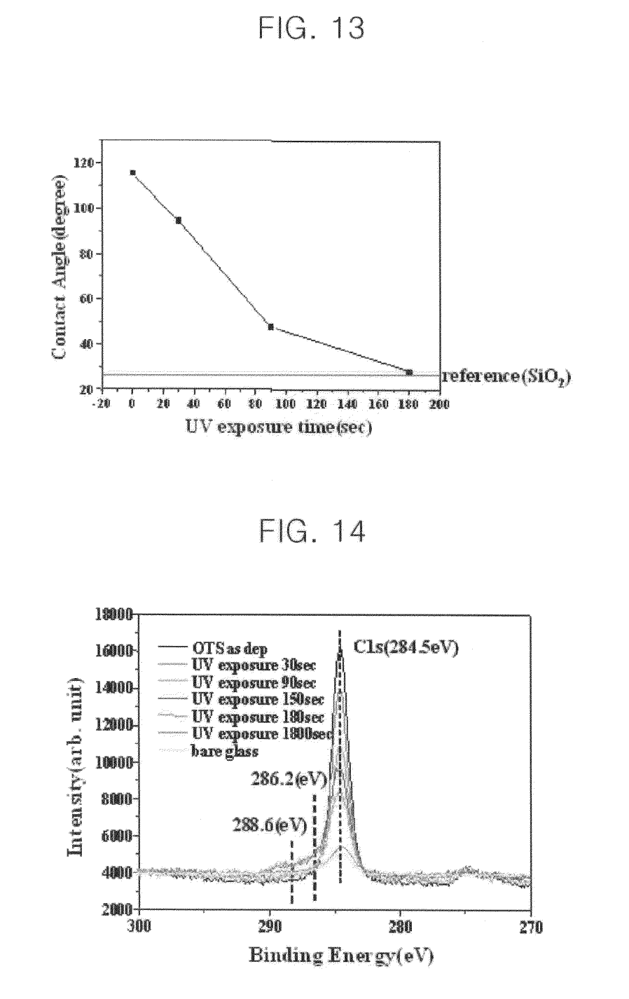

Referring to FIG. 13, the contact angles were measured at various ultraviolet light exposure times when OTS/SiO₂ was exposed to the ultraviolet light. The data in FIG. 13 help determine the reason that FeCl₃ applicability of the self-assembled monolayer formed on the oxide layer was changed according to the ultraviolet light exposure time. The contact angle was obtained by placing a drop of water on the substrate and measuring the angle formed between the drop of water and the substrate surface. It can be seen from the contact angles that the surface of the OTS/SiO₂ was gradually changed from hydrophobic to hydrophilic according to the exposure time of the ultraviolet light and thus the FeCl₃ can be uniformly coated on the surface.

FIG. 14 is a graph showing results of X-ray analyses by varying the time for exposing the OTS/SiO₂ sample to the ultraviolet light in order to determine the surface change of the self-assembled monolayer according to the ultraviolet light exposure time on the basis of the result of FIG. 13. The graph indicates that the CH₂ chains of the self-assembled monolayer were stably broken by the oxygen radicals generated by the ultraviolet light. That is, the oxygen radicals generated within a chamber reacted with the carbon of the OTS at a certain section according to the exposure time to form C—O and C═O (binding energy: 286.2 eV and 288.6 eV) on the substrate surface, thereby gradually changing the substrate surface to hydrophilic.

Although the CH₂ chains of the self-assembled monolayer were not perfectly removed as numerous C—O and C═O were formed on the surface, especially at the 150-second section, the surface was changed so that it is as hydrophilic as bare SiO₂. According to such results, the coating layer was uniformly and stably formed by spin-coating the FeCl₃ on the substrate and, if PEDOT was deposited on the substrate, the carbon of the substrate surface was stably combined with a carbon monomer to increase the adhesive strength between the PEDOT and the SiO₂ substrate, thus showing a stable deposition characteristic as shown in FIG. 11.

In accordance with the present invention, it is possible to form a conductive polymer that adheres well to the oxide layer and is capable of being patterned exactly.

The conductive polymer formed on the oxide layer in accordance with the present invention can be effectively used in the semiconductor memory device fields, such as with an organic thin-film transistor to be used in a next generation display device, a smart card, a next generation semiconductor wiring process and the like. The conductive polymer of the invention significantly improves the adhesive property between inorganics and organics, and simultaneously allows easy formation of a polymer pattern.

Although exemplary embodiments of the present invention have been described, it is understood that the present invention should not be limited to these exemplary embodiments but various changes and modifications can be made by one of ordinary skill in the art within the spirit and scope of the present invention as hereinafter claimed.

What is claimed is:

1. A method for patterning a conductive polymer comprising:
forming a self-assembled monolayer on a substrate;
patterning the self-assembled monolayer;
forming a catalyst layer on the self-assembled monolayer; and
forming a conductive polymer layer on the self-assembled monolayer.

2. The method of claim 1, further comprising forming an insulating layer between the substrate and the self-assembled monolayer.

3. The method of claim 1, wherein the conductive polymer layer comprises a polythiophene based material or a polyaniline based material.

4. The method of claim 3, wherein the conductive polymer layer comprises poly 3,4-ethylenedioxythiophene (PEDOT).

5. The method of claim 1, wherein the insulating layer is an oxide layer.

6. The method of claim 5, wherein the self-assembled monolayer is an octadecyltrichlorosilane (OTS) based self-assembled monolayer.

7. The method of claim 5, wherein forming the self-assembled monolayer comprises:
preparing a self-assembled monolayer solution by dissolving the self-assembled monolayer in a solvent; and
dipping the substrate on which an oxide layer is formed in the self-assembled monolayer solution.

8. The method of claim 7, wherein the solvent is hexane.

9. The method of claim 5, wherein patterning the self-assembled monolayer comprises:
forming a mask defining an exposure area and a non-exposure area in the self-assembled monolayer;
aligning the mask on the substrate; and
irradiating the mask with ultraviolet light.

10. The method of claim 9, wherein the mask comprises a blocking layer of a chromium material formed on a quartz substrate.

11. The method of claim 9, wherein the mask is irradiated for about 10 to 15 minutes.

12. The method of claim 5, wherein the catalyst layer is formed using a spin coating process.

13. The method of claim 12, wherein the catalyst is an oxidizing agent.

14. The method of claim 13, wherein the oxidizing agent is FeCl₃.

15. The method of claim 5, wherein the conductive polymer layer is formed using a vapor deposition process.

16. The method of claim 15, wherein forming the conductive polymer layer comprises:
heating 3,4-Ethylenedioxythiophene (EDOT) to be vaporized; and
forming a PEDOT layer by depositing the vaporized EDOT on the substrate.

17. The method of claim 5, further comprising removing organic materials on the substrate before forming the self-assembled monolayer.

18. The method of claim 17, wherein removing the organic materials comprises:
dipping the substrate in a detergent solution; and
rinsing the substrate.

19. The method of claim 18, wherein the detergent solution comprises sulfuric acid (H₂SO₄) and hydrogen peroxide (H₂O₂) mixed in a volumetric ratio of 4:1.

20. The method of claim 18, wherein the substrate is dipped in the detergent solution for about 8 to about 12 minutes.

21. The method of claim 18, wherein the substrate is rinsed using deionized water.

22. The method of claim 5 further comprising removing the catalyst remaining on the substrate after forming the conductive polymer layer.

23. The method of claim 22, wherein the substrate is rinsed using a catalyst removing solvent.

24. The method of claim 23, wherein the catalyst removing solvent is methanol.

25. The method of claim 5, wherein the oxide layer comprises at least one of SiO₂, TiO₂, ZrO₂, and HfO₂.

26. The method of claim 5, wherein the oxide layer is formed by heating the substrate.

27. The method of claim 26, wherein the oxide layer is formed in a thickness of about 800 Å to about 1200 Å.
